(19) United States
(12) Patent Application Publication
(10) Pub. No.: US 2026/0144151 A1
(43) Pub. Date: May 21, 2026

(54) SEMICONDUCTOR PACKAGE INCLUDING TOP DIE

(71) Applicant: Samsung Electronics Co., Ltd., Suwon-si (KR)

(72) Inventors: Dawoon Jung, Suwon-si (KR); Haseob Seong, Suwon-si (KR)

(21) Appl. No.: 19/388,718

(22) Filed: Nov. 13, 2025

(30) Foreign Application Priority Data
Nov. 15, 2024 (KR) 10-2024-0162902

(51) Int. Cl. H01L 25/18; H01L 23/00; H10B 80/00; H10D 80/30

(52) U.S. Cl. CPC H10W 90/00; H10B 80/00; H10D 80/30; H10W 72/944; H10W 80/743; H10W 90/297; H10W 90/792

(57) ABSTRACT

A semiconductor package includes a buffer die, middle core dies stacked in a vertical direction on the buffer die, a top core die on an uppermost one of the middle core die, dummy dies stacked in the vertical direction on the top core die, a first bonding layer structure between the middle core dies and including a first bonding pad structure, a second bonding layer structure between the top core and a lowermost one of the dummy dies, and a third bonding layer structure between the dummy dies.

### CROSS-REFERENCE TO RELATED APPLICATION

This application claims priority under 35 U.S.C. § 119 to Korean Patent Application No. 10-2024-0162902, filed on November 15, 2024, in the Korean Intellectual Property Office (KIPO), the contents of which are herein incorporated by reference in their entirety.

### BACKGROUND

A high bandwidth memory (HBM) package may include a plurality of memory chips stacked on a logic chip in a vertical direction, and the memory chips may be bonded with each other by a bonding layer.

### SUMMARY

If a bonding state between memory chips in a HBM package is good, the HBM package may have enhanced performance. Some aspects of this disclosure provide methods and semiconductor packages providing enhanced bonding states between memory chips.

For example, some implementations according to the present disclosure provide semiconductor packages having enhanced electrical characteristics.

According to some implementations, there is provided a semiconductor package. The semiconductor package may include a buffer die, middle core dies stacked in a vertical direction on the buffer die, a top core die on an uppermost one of the middle core die, dummy dies stacked in the vertical direction on the top core die, a first bonding layer structure between the middle core dies and including a first bonding pad structure, a second bonding layer structure between the top core and a lowermost one of the dummy dies, and a third bonding layer structure between the dummy dies.

According to some implementations, there is provided a semiconductor package. The semiconductor package may include a first semiconductor chip, second semiconductor chips, a third semiconductor chip, dummy chips, a first bonding layer structure, a second bonding layer structure, a third bonding layer structure and a fourth bonding layer structure. The second semiconductor chips may be stacked in a vertical direction on the first semiconductor chip. Each of the second semiconductor chips may include a substrate and a through electrode extending through the substrate in the vertical direction. The third semiconductor chip may be disposed on an uppermost one of the second semiconductor chips. The dummy chips may be stacked in the vertical direction on the third semiconductor chip. The first bonding layer structure may be between ones of the second semiconductor chips neighboring in the vertical direction. The first bonding layer may include a first bonding pad structure electrically connected to the through electrode included in at least one of the second semiconductor chips. The second bonding layer structure may be disposed between an uppermost one of the second semiconductor chips and the third semiconductor chip. The second bonding layer may include a second bonding pad structure electrically connected to the through electrode included in the uppermost one of the second semiconductor chips. The third bonding layer structure may be disposed between the third semiconductor chip and a lowermost one of the dummy chips. The fourth bonding layer structure may be disposed between the dummy chips.

According to some implementations, there is provided a semiconductor package. The semiconductor package may include a first semiconductor chip, a first bonding layer structure, second semiconductor chips, a second bonding layer structure, a third bonding layer structure, a third semiconductor chip, a fourth bonding layer structure, dummy chips, a fifth bonding layer structure and a molding member. The first semiconductor chip may include a first substrate, and a first through electrode extending through the first substrate in the vertical direction. The first bonding layer structure may be disposed on the first semiconductor chip, and may include a first bonding pad structure electrically connected to the first through electrode. The second semiconductor chips may be stacked in the vertical direction on the first bonding layer. Each of the second semiconductor chips may include a second substrate, and a second through electrode extending through the second substrate in the vertical direction. The second bonding layer structure may be disposed between ones of the second semiconductor chips neighboring in the vertical direction, and may include a second bonding pad structure electrically connected to the second through electrode included in at least one of the second semiconductor chips. The third bonding layer structure may be disposed on an uppermost one of the second semiconductor chips, and may include a third bonding pad structure electrically connected to the second through electrode included in the uppermost one of the second semiconductor chips. The third semiconductor chip may be disposed on the third bonding layer structure. The fourth bonding layer structure may be disposed on the third semiconductor chip. The dummy chips may be stacked in the vertical direction on the fourth bonding layer structure. The fifth bonding layer structure may be disposed between ones of the dummy chips neighboring in the vertical direction. The molding member may be disposed on the first semiconductor chip, and may cover sidewalls of the first to third semiconductor chips, the dummy chips and the first to fifth bonding layer structures.

According to some implementations, a semiconductor package may include a plurality of semiconductor chips stacked in the vertical direction, and the bonding layer structure for bonding the semiconductor chips to each other may not include voids therein. Thus, the semiconductor chips may be well bonded to each other so that the semiconductor package may have enhanced structural and electrical characteristics.

### BRIEF DESCRIPTION OF THE DRAWINGS

FIG. 1 is a cross-sectional view illustrating an example of a semiconductor package.

FIGS. 2 to 8 are cross-sectional views illustrating an example of a method of manufacturing a semiconductor package.

FIGS. 9 to 11 are cross-sectional views illustrating examples of semiconductor packages.

FIGS. 12 and 13 are cross-sectional views illustrating examples of semiconductor packages.

FIG. 14 is a cross-sectional view illustrating an example of an electronic device in accordance.

### DETAILED DESCRIPTION

It will be understood that, although the terms “first,” “second,” and/or “third” (etc.) may be used herein to describe various elements, components, regions, layers and/or sections, these terms are only used to distinguish one element, component, region, layer or section from another region, layer or section, and are not meant to require any particular ordering. Thus, a first element, component, region, layer or section discussed below could be termed a second or third element, component, region, layer or section without departing from the scope of this disclosure.

Hereinafter, a direction substantially parallel to an upper surface of a wafer or a substrate may be referred to as a horizontal direction, and a direction substantially perpendicular to the upper surface of the wafer or the substrate may be referred to as a vertical direction.

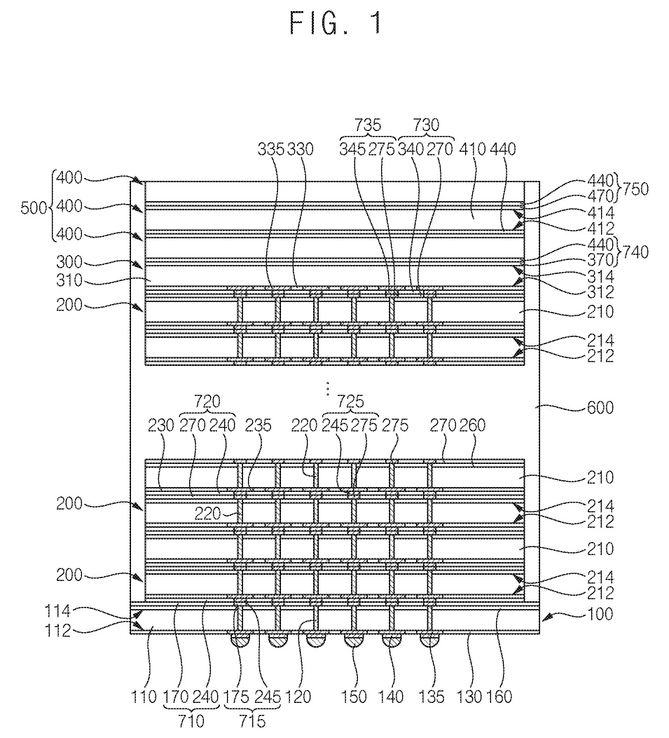

FIG. 1 is a cross-sectional view illustrating an example of a semiconductor package. Referring to FIG. 1, the semiconductor package may include a first semiconductor chip 100, a plurality of semiconductor chips stacked on the first semiconductor chip 100 in the vertical direction, a third semiconductor chip on an uppermost one of the second semiconductor chips 200, and a dummy chip stack structure 500 on the third semiconductor chip 300.

The semiconductor package may further include first to fifth bonding layer structures 710, 720, 730, 740 and 750, a conductive pad 140, a first conductive connection member 150, and a molding member 600.

In some implementations, the semiconductor package may be a high bandwidth memory (HBM) package.

In some implementations, the first semiconductor chip 100 may be a buffer die, and may include a logic device, e.g., a controller. Each of the second and third semiconductor chips 200 and 300 may be a core die, and may include a volatile memory device, e.g., a DRAM device, an SRAM device, etc., or a non-volatile memory device, e.g., a flash memory device, an EEPROM device, etc. Each of the second semiconductor chips 200 may also be referred to as a middle core die, and the third semiconductor chip 300 may also be referred to as a top core die.

Additionally, the first semiconductor chip 100 may also be referred to as a logic chip or logic die, and each of the second and third semiconductor chips 200 and 300 may also be referred to as a memory chip or a memory die.

The first semiconductor chip 100 may include a first substrate 110 having first and second surfaces 112 and 114 opposite to each other in the vertical direction, a first through electrode structure 120 extending through the first substrate 110, a first insulating interlayer and a second insulating interlayer 130 sequentially stacked in the vertical direction on the first surface 112 of the first substrate 110, and a first protective pattern structure 160 on the second surface 114 of the first substrate 110.

The first substrate 110 may include a semiconductor material, e.g., silicon, germanium, silicon-germanium, or a Ⅲ-Ⅴ group compound semiconductor, e.g., GaP, GaAs, GaSb, etc. In some implementations, the first substrate 110 may be a silicon-on-insulator (SOI) substrate or a germanium-on-insulator (GOI) substrate.

A circuit device, e.g., a logic device may be disposed on the first surface 112 of the first substrate 110. The circuit device may include circuit patterns, which may be covered by the first insulating interlayer.

The second insulating interlayer 130 may contain a first wiring structure 135 therein. The first wiring structure 135 may include, e.g., wirings, vias, contact plugs, etc., and FIG. 1 shows only a single layer for the first wiring structure 135 in order to reduce the complexity of the drawing, for clarity.

The first insulating interlayer and the second insulating interlayer 130 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

The conductive pad 140 may be disposed on a lower surface of the second insulating interlayer 130, and may contact the first wiring structure 135 to be electrically connected thereto. In some implementations, a plurality of conductive pads 140 may be spaced apart from each other in the horizontal direction.

In some implementations, the conductive pad 140 may include a first seed pattern and first and second conductive patterns sequentially stacked downwardly in the vertical direction from the lower surface of the second insulating interlayer 130. The first seed pattern may include, e.g., titanium, and the first and second conductive patterns may include, e.g., nickel and gold, respectively.

The first conductive connection member 150 may contact a lower surface of the conductive pad 140. The conductive connection member 150 may be, e.g., a conductive bump or a conductive ball. The conductive connection member 150 may include a metal, e.g., tin, or solder that is a tin alloy such as tin/silver, tin/copper, tin/indium, tin/silver/copper, etc.

The first through electrode structure 120 may extend through the first substrate 110 in the vertical direction. A portion of the first through electrode structure 120 may protrude upwardly in the vertical direction, which may be referred to as a protrusion portion, and a sidewall of the protrusion portion of the first through electrode structure 120 may be covered by the first protective pattern structure 160. A plurality of first through electrode structures 120 may be spaced apart from each other in the horizontal direction. In some implementations, the first through electrode structure 120 may include a first through electrode extending in the vertical direction, a first barrier pattern covering a sidewall of the first through electrode, and a first insulation pattern covering an outer sidewall of the first barrier pattern. However, in some implementations, the first insulation pattern may not cover an upper portion of the outer sidewall of the first barrier pattern.

The first through electrode may include a metal, e.g., copper, aluminum, etc., the first barrier pattern may include a metal nitride, e.g., titanium nitride, tantalum nitride, etc., and the first insulation pattern may include an oxide, e.g., silicon oxide or an insulating nitride, e.g., silicon nitride.

In some implementations, the first through electrode structure 120 may extend through the first protective pattern structure 160, the first substrate 110 and the first insulating interlayer to contact the first wiring structure 135, and may be electrically connected to the conductive pad 140 by the first wiring structure 135.

As another example, the first through electrode structure 120 may extend through the first protective pattern structure 160, the first substrate 110, the first insulating interlayer and the second insulating interlayer 130 to contact the conductive pad 140, and may be electrically connected thereto. As another example, the first through electrode structure 120 may extend through the first protective pattern structure 160 and the first substrate 110 to contact one of the circuit patterns included in the circuit device covered by the first insulating interlayer, and may be electrically connected to the conductive pad 140 by the one of the first circuit patterns and the first wiring structure 135.

The first protective pattern structure 160 may be disposed on the second surface 114 of the first substrate 110, and may surround the protrusion portion of the first through electrode structure 120. In some implementations, the first protective pattern structure 160 may contact an outer sidewall of an upper portion of the first barrier pattern of the first through electrode structure 120.

In some implementations, the first protective pattern structure 160 may include a first protective pattern and a second protective pattern sequentially stacked in the vertical direction on the second surface 114 of the first substrate 110. A portion of the first protective pattern adjacent to the first through electrode structure 120 may protrude upwardly in the vertical direction, and an upper surface of the portion of the first protective pattern 161 may be substantially coplanar with an upper surface of the first through electrode structure 120. An outer sidewall of the portion of the first protective pattern 161 may be covered by the second protective pattern.

The first protective pattern may include an oxide, e.g., silicon oxide, and the second protective pattern may include an insulating nitride, e.g., silicon nitride.

A first bonding layer 170 may be disposed on the first protective pattern structure 160 and the first through electrode structure 120, and may include a first bonding pad 175. In some implementations, a plurality of first bonding pads 175 may be spaced apart from each other in the horizontal direction, and may contact upper surfaces of the first through electrode structures 120, respectively.

In some implementations, the first bonding layer 170 may include an insulating material, e.g., silicon carbonitride, silicon nitride, silicon oxide, etc., and the first bonding pad 175 may include a metal, e.g., copper.

In some implementations, a thickness in the vertical direction of the first semiconductor chip 100 may be in a range of about 50um to about 120um, and a thickness in the vertical direction of the first bonding layer 170 on the first semiconductor chip 100 may be equal to or less than about 1um.

Each of the second semiconductor chips 200 may include a second substrate 210 having first and second surfaces 212 and 214 opposite to each other in the vertical direction, a third insulating interlayer and a fourth insulating interlayer 230 sequentially stacked in the vertical direction on the first surface 212 of the second substrate 210, and a second protective pattern structure 260 on the second surface 214 of the second substrate 210.

The second semiconductor chips 200 may be stacked in, e.g., three levels, seven levels, eleven levels, etc., however, the number of levels is not limited thereto, and any number of the second semiconductor chips 200 may be included.

The second substrate 210 may include a semiconductor material, e.g., silicon, germanium, silicon-germanium, or a Ⅲ-Ⅴ group compound semiconductor, e.g., GaP, GaAs, GaSb, etc. In some implementations, the second substrate 210 may be a silicon-on-insulator (SOI) substrate or a germanium-on-insulator (GOI) substrate.

A circuit device, e.g., a volatile memory device such as a DRAM device, an SRAM device, etc., or a non-volatile memory device such as a flash memory device, an EEPROM device, etc., may be disposed on the first surface 212 of the second substrate 210. The circuit device may include circuit patterns, which may be covered by the third insulating interlayer.

The fourth insulating interlayer 230 may contain a second wiring structure 235 therein. The second wiring structure 235 may include, e.g., wirings, vias, contact plugs, etc., and FIG. 1 shows only a single layer for the second wiring structure 235 in order to reduce the complexity of the drawing, for clarity.

The third insulating interlayer and the fourth insulating interlayer 230 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

A second bonding layer 240 may be disposed on a lower surface of the fourth insulating interlayer 230, and may include a second bonding pad 245. In some implementations, a plurality of second bonding pads 245 may be spaced apart from each other in the horizontal direction, and each of the second bonding pads 245 may contact a portion of the second wiring structure 235 to be electrically connected thereto.

In some implementations, the second bonding layer 240 may include an insulating material, e.g., silicon carbonitride, silicon nitride, silicon oxide, etc., and the second bonding pad 245 may include a metal, e.g., copper.

In some implementations, a lower surface of the second bonding layer 240 on a lower surface of a lowermost one of the second semiconductor chips 200 may contact an upper surface of the first bonding layer 170 on the first semiconductor chip 100 so that the first bonding layer structure 710 may be formed, and the second bonding pads 245 in the second bonding layer 240 may be bonded to the first bonding pads 175 in the first bonding layer 170 so that a first bonding pad structure 715 may be formed.

The first and second bonding layers 170 and 240 may include substantially the same material (e.g., so as to not be distinguished from each other), or may include different materials so as to be distinguished from each other. The first and second bonding pads 175 and 245 may include substantially the same material so as to not to distinguished from each other, or may include different materials so as to be distinguished from each other.

The second through electrode structure 220 may extend through the second substrate 210 in the vertical direction. A portion of the second through electrode structure 220 may protrude upwardly in the vertical direction, which may be referred to as a protrusion portion, and a sidewall of the protrusion portion of the second through electrode structure 220 may be covered by the second protective pattern structure 260. A plurality of second through electrode structures 220 may be spaced apart from each other in the horizontal direction. In some implementations, the second through electrode structure 220 may include a second through electrode extending in the vertical direction, a second barrier pattern covering a sidewall of the second through electrode, and a second insulation pattern covering an outer sidewall of the second barrier pattern. However, in some implementations, the second insulation pattern may not cover an upper portion of the outer sidewall of the second barrier pattern.

The second through electrode may include a metal, e.g., copper, aluminum, etc., the second barrier pattern may include a metal nitride, e.g., titanium nitride, tantalum nitride, etc., and the second insulation pattern may include an oxide, e.g., silicon oxide or an insulating nitride, e.g., silicon nitride.

In some implementations, the second through electrode structure 220 may extend through the second protective pattern structure 260, the second substrate 210 and the third insulating interlayer to contact the second wiring structure 235, and may be electrically connected to the second bonding pad 245 by the second wiring structure 235.

As another example, the second through electrode structure 220 may extend through the second protective pattern structure 260, the second substrate 210 and the third insulating interlayer and the fourth insulating interlayer 230 to contact the second bonding pad 245, and may be electrically connected thereto. As another example, the second through electrode structure 220 may extend through the second protective pattern structure 260 and the second substrate 210 to contact one of the circuit patterns included in the circuit device covered by the third insulating interlayer, and may be electrically connected to the second bonding pad 245 by the one of the circuit patterns and the second wiring structure 235.

The second protective pattern structure 260 may be disposed on the second surface 214 of the second substrate 210, and may surround the protrusion portion of the second through electrode structure 220. In some implementations, the second protective pattern structure 260 may contact an outer sidewall of an upper portion of the second barrier pattern of the second through electrode structure 220.

In some implementations, the second protective pattern structure 260 may include a third protective pattern and a fourth protective pattern sequentially stacked in the vertical direction on the second surface 214 of the second substrate 210. A portion of the third protective pattern adjacent to the second through electrode structure 220 may protrude upwardly in the vertical direction, and an upper surface of the portion of the second protective pattern may be substantially coplanar with an upper surface of the second through electrode structure 220. An outer sidewall of the portion of the third protective pattern may be covered by the fourth protective pattern.

The third protective pattern may include an oxide, e.g., silicon oxide, and the fourth protective pattern may include an insulating nitride, e.g., silicon nitride.

A third bonding layer 270 may be disposed on the second protective pattern structure 260 and the second through electrode structure 220, and may include a third bonding pad 275. In some implementations, a plurality of third bonding pads 275 may be spaced apart from each other in the horizontal direction, and may contact upper surfaces of the second through electrode structures 220, respectively.

In some implementations, the third bonding layer 270 may include an insulating material, e.g., silicon carbonitride, silicon nitride, silicon oxide, etc., and the third bonding pad 275 may include a metal, e.g., copper.

In some implementations, a thickness in the vertical direction of each of the second semiconductor chips 200 may be in a range of about 30um to about 100um, and a thickness in the vertical direction of each of the second and third bonding layers 240 and 270 may be equal to or less than about 1um.

In some implementations, the lower surface of the second bonding layer 240 on a lower surface of an upper one of the second semiconductor chips 200 may contact an upper surface of the third bonding layer 270 on a lower one of the second semiconductor chips 200 so that a second bonding layer structure 720 may be formed, and the second bonding pads 245 in the second bonding layer 240 may be bonded to the third bonding pads 275 in the third bonding layer 270 so that a second bonding pad structure 725 may be formed.

The second and third bonding layers 240 and 270 may include substantially the same material so as to not be distinguished from each other, or may include different materials to be distinguished from each other. The second and third bonding pads 245 and 275 may include substantially the same material so as to not be distinguished from each other, or may include different materials to be distinguished from each other.

The third semiconductor chip 300 may include a third substrate 310 having first and second surfaces 312 and 314 opposite to each other in the vertical direction, a fifth insulating interlayer and a sixth insulating interlayer 330 sequentially stacked in the vertical direction on the first surface 312 of the third substrate 310.

A circuit device, e.g., a volatile memory device or a non-volatile memory device may be disposed beneath the first surface 312 of the third substrate 310. The circuit device may include circuit patterns, which may be covered by the fifth insulating interlayer. The sixth insulating interlayer 330 may contain a third wiring structure 335 therein.

A fourth bonding layer 340 may be disposed on a lower surface of the sixth insulating interlayer 330, and may include a fourth bonding pad 345. In some implementations, a plurality of fourth bonding pads 345 may be spaced apart from each other in the horizontal direction, and each of the fourth bonding pads 345 may contact a portion of the third wiring structure 335 to be electrically connected thereto.

A fifth bonding layer 370 may be disposed on the second surface 314 of the third substrate 310.

In some implementations, each of the fourth and fifth bonding layers 340 and 370 may include an insulating material, e.g., silicon carbonitride, silicon nitride, silicon oxide, etc., and the fourth bonding pad 345 may include a metal, e.g., copper.

In some implementations, a thickness in the vertical direction of the third semiconductor chip 300 may be in a range of about 30um to about 100um, and a thickness in the vertical direction of each of the fourth and fifth bonding layers 340 and 370 may be equal to or less than about 1um. In some implementations, the thickness in the vertical direction of the third semiconductor chip 300 may be substantially equal to the thickness in the vertical direction of each of the second semiconductor chips 200.

In some implementations, a lower surface of the fourth bonding layer 340 on a lower surface of the third semiconductor chip 300 may contact an upper surface of the third bonding layer 270 on an uppermost one of the second semiconductor chips 200 so that the third bonding layer structure 730 may be formed, and the fourth bonding pads 345 in the fourth bonding layer 340 may be bonded to the third bonding pads 275 in the third bonding layer 270 so that a third bonding pad structure 735 may be formed.

The third and fourth bonding layers 270 and 340 may include substantially the same material so as to not be distinguished from each other, or may include different materials to be distinguished from each other. The third and fourth bonding pads 275 and 345 may include substantially the same material so as to not be distinguished from each other, or may include different materials to be distinguished from each other.

The dummy chip stack structure 500 may include a plurality of dummy chips 400 stacked in the vertical direction, and the fifth bonding layer structure 750 therebetween.

FIG. 1 shows that the dummy chip stack structure 500 includes three dummy chips 400, however, the number of dummy chips 400 is not limited thereto.

Each of the dummy chips 400 may include a fourth substrate 410 having first and second surfaces 412 and 414 opposite to each other in the vertical direction. The fourth substrate 410 may include a semiconductor material, e.g., silicon, germanium, silicon-germanium, or a Ⅲ-Ⅴ group compound semiconductor, e.g., GaP, GaAs, GaSb, etc. As another example, the fourth substrate 410 may include, e.g., glass, an inorganic insulating material, an organic material, etc.

A sixth bonding layer 440 may be disposed on the first surface 412 of the fourth substrate 410, and a seventh bonding layer 470 may be disposed on the second surface 414 of the fourth substrate 410. However, in some implementations, the seventh bonding layer 470 may not be disposed on the second surface 414 of an uppermost one of the dummy chips 400, which is shown in FIG. 1.

A lower surface of the sixth bonding layer 440 on a lower surface of a lowermost one of the dummy chip 400 may contact an upper surface of the fifth bonding layer 370 on an upper surface of the third semiconductor chip 300 so that the fourth bonding layer structure 740 may be formed. A lower surface of the sixth bonding layer 440 on a lower surface of an upper one of the dummy chips 400 may contact an upper surface of the seventh bonding layer 470 on an upper surface of a lower one of the dummy chips 400 so that the fifth bonding layer structure 750 may be formed.

In some implementations, each of the sixth and seventh bonding layers 440 and 470 may include an insulating material, e.g., silicon carbonitride, silicon nitride, silicon oxide, etc.

The fifth and sixth bonding layers 370 and 440 may include substantially the same material so as to not be distinguished from each other, or may include different materials to be distinguished from each other. The sixth and seventh bonding layers 440 and 470 may include substantially the same material so as to not be distinguished from each other, or may include different materials to be distinguished from each other.

In some implementations, a thickness in the vertical direction of each of the dummy chips 400 may be in a range of about 30um to about 60um, and a thickness in the vertical direction of each of the sixth and seventh bonding layers 440 and 470 may be equal to or less than about 1um.

In some implementations, the thickness in the vertical direction of each of the dummy chips 400 may be substantially equal to or less than the thickness in the vertical direction of each of the second and third semiconductor chips 200 and 300. The thickness in the vertical direction of the dummy chips 400 may be substantially equal to or different from each other.

In some implementations, a sum of the thickness in the vertical direction of the dummy chips 400 included in the dummy chip stack structure 500, or a thickness in the vertical direction of the dummy chip stack structure 500 may be greater than the thickness in the vertical direction of each of the first to third semiconductor chips 100, 200 and 300.

In some implementations, each of the first to third semiconductor chips 100, 200 and 300, the dummy chips 400 and the dummy chip stack structure 500 may have a shape of a flat plate, and may have a shape of a rectangle in a plan view.

The molding member 600 may be disposed on the first semiconductor chip 100, and may cover sidewalls of the second and third semiconductor chips 200 and 300, the first to fourth bonding layer structures 710, 720, 730 and 740 and the dummy chip stack structure 500, and an upper surface of the molding member 600 may be substantially coplanar with an upper surface of the dummy chip stack structure 500.

The molding member 600 may include a polymer, e.g., epoxy molding compound (EMC).

In the semiconductor package, the second semiconductor chips 200 stacked on the first semiconductor chip 100 may be bonded with each other by a hybrid copper bonding (HCB) process, as illustrated below with reference to FIGS. 2 to 8. HCB features a copper-copper bond between chips. For example, the second semiconductor chips 200 may be bonded with each other through the second bonding layer structure 720 including the second and third bonding layers 240 and 270 and the second bonding pad structure 725 including the second and third bonding pads 245 and 275.

During the HCB process, voids may be generated between the second and third bonding layers 240 and 270, however, as each of the second semiconductor chips 200 may have a thin thickness, pressure may be applied to the upper surface of the uppermost one of the second semiconductor chips 200 so that the voids may be expelled outwardly.

The third semiconductor chip 300 and a lowermost one of the dummy chips 400 may be bonded to each other through the fourth bonding layer structure 740 including the fifth and sixth bonding layers 370 and 440 stacked in the vertical direction, and the dummy chips 400 stacked in the vertical direction may be bonded to each other through the fifth bonding layer structure 750 including the sixth and seventh bonding layers 440 and 470 stacked in the vertical direction.

When the dummy chips 400 are stacked on the third semiconductor chip 300, voids may be generated between the fifth and sixth bonding layers 370 and 440 and/or between the sixth and seventh bonding layers 440 and 470, however, as each of the dummy chips 400 may have a thin thickness, pressure may be applied to the upper surface of the uppermost one of the dummy chips 400 so that the voids may be expelled outwardly. Accordingly, the lowermost one of the dummy chips 400 and the third semiconductor chip 300 may be well bonded to each other without reduction of the adhesion therebetween, and likewise, the dummy chips 400 may also be well bonded to each other.

As a result, the semiconductor package including the first to third semiconductor chips 100, 200 and 300 and the dummy chips 400 may have enhanced structural and electrical characteristics.

FIGS. 2 to 8 are cross-sectional views illustrating an example of a method of manufacturing a semiconductor package.

Referring to FIG. 2, a first wafer W1 may be provided.

In some implementations, the first wafer W1 may include a first substrate 110 having first and second surfaces 112 and 114 opposite to each other in the vertical direction. Additionally, the first wafer W1 may include a plurality of die regions DR and a scribe lane region SR surrounding each of the die regions DR. The first wafer W1 may be cut along the scribe lane region SR by a sawing process to be singulated into a plurality of first semiconductor chips.

In the die region DR, a circuit device may be formed on the first surface 112 of the first substrate 110. The circuit device may include a logic device. The circuit device may include circuit patterns, and a first insulating interlayer may be formed on the first surface 112 of the first substrate 110 to cover the circuit patterns.

A second insulating interlayer 130 may be formed on the first insulating interlayer, and may include a first wiring structure 135 therein.

A conductive pad 140 may be formed on second insulating interlayer 130 to contact the first wiring structure 135 to be electrically connected thereto. In some implementations, the conductive pad 140 may be formed by the following processes.

A first seed layer may be formed on the second insulating interlayer 130, a first photoresist pattern including a first opening partially exposing an upper surface of the first seed layer may be formed on the first seed layer, and an electroplating process or an electroless plating process may be performed to form first and second conductive patterns in the first opening.

The first photoresist pattern may be removed by, e.g., an ashing process and/or a stripping process to expose a portion of the first seed layer, and the exposed portion of the first seed layer may be removed to form a first seed pattern under the first conductive pattern.

Thus, the conductive pad 140 including the first seed pattern and the first and second conductive patterns sequentially stacked in the vertical direction may be formed.

A first conductive connection member 150 may be formed on the conductive pad 140. In some implementations, the first conductive connection member 150 may be formed by the following processes.

A second photoresist pattern including a second opening exposing an upper surface of the conductive pad 140 may be formed on the second insulating interlayer 130, and an electroplating process or an electroless plating process may be performed to form a preliminary first conductive connection member in the second opening. After removing the second photoresist pattern, a reflow process may be performed so that the preliminary first conductive connection member may be transformed into a first conductive connection member 150.

In some implementations, the first conductive connection member 150 may have, e.g., a hemispherical shape or a semioval shape.

In some implementations, a first through electrode structure 120 extending in the vertical direction through an upper portion of the first substrate 110, that is, a portion of the first substrate 110 adjacent to the first surface 112 thereof may be formed. In some implementations, a plurality of first through electrode structures 120 may be spaced apart from each other in the horizontal direction in each of the die regions DR of the first wafer W1.

In some implementations, the first through electrode structure 120 may include a first through electrode extending in the vertical direction, a first barrier pattern covering a sidewall and a lower surface of the first through electrode, and a first insulation pattern covering a sidewall and a lower surface of the first barrier pattern.

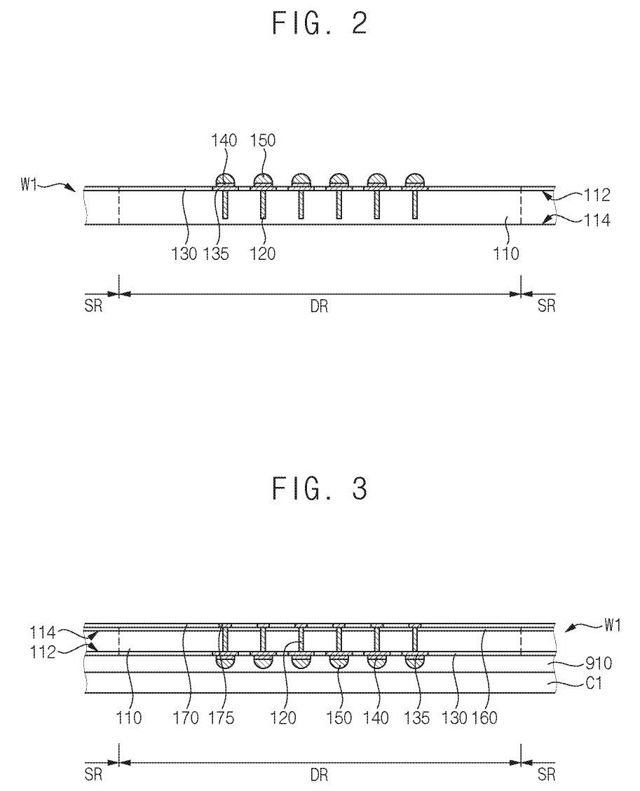

Referring to FIG. 3, a first temporary bonding layer 910 may be attached to a first carrier substrate C1, and the first temporary bonding layer 910 may be bonded to an upper surface of the second insulating interlayer 130 including the first wiring structure 135 to cover the first conductive connection member 150 and the conductive pad 140 on the first wafer W1 so that the first carrier substrate C1 may be bonded to the first wafer W1.

The first temporary bonding layer 910 may include a material that may lose adhesion by irradiation of light, e.g., UV light or heat. In some implementations, the first temporary bonding layer 910 may include glue.

After flipping the first wafer W1, a portion of the first substrate 110 adjacent to the second surface 114 of the first substrate 110 may be removed by, e.g., a grinding process to expose an upper portion of the first through electrode structure 120.

In some implementations, an upper portion of the first insulation pattern of the first through electrode structure 120 may also be removed by the grinding process, and thus an upper surface and an upper outer sidewall of the first barrier pattern may be exposed.

A first protective layer structure may be formed on the second surface 114 of the first substrate 110 to cover the first through electrode structure 120, and a planarization process may be performed on the first protective layer structure until an upper surface of the first through electrode of the first through electrode structure 120 is exposed to form a first protective pattern structure 160.

In some implementations, the planarization process may include a chemical mechanical polishing (CMP) process and/or an etch back process.

In some implementations, the first protective layer structure may include first to third protective layers sequentially stacked in the vertical direction, and during the planarization process, the third protective layer may be removed and the second protective layer may partially remain. Thus, the first protective pattern structure 160 may include first and second protective patterns sequentially stacked in the vertical direction. An upper outer sidewall of a portion of the first protective pattern adjacent to the first through electrode structure 120 may be covered by the second protective pattern.

A first bonding layer 170 including a first bonding pad 175 therein may be formed on the first protective pattern structure 160 and the first through electrode structure 120.

In some implementations, a plurality of first bonding pads 175 may be spaced apart from each other in the horizontal direction, and may contact upper surfaces of the first through electrode structures 120, respectively.

In some implementations, the first bonding layer 170 may include an insulating material, e.g., silicon carbonitride, silicon nitride, silicon oxide, etc., and the first bonding pad 175 may include a metal, e.g., copper.

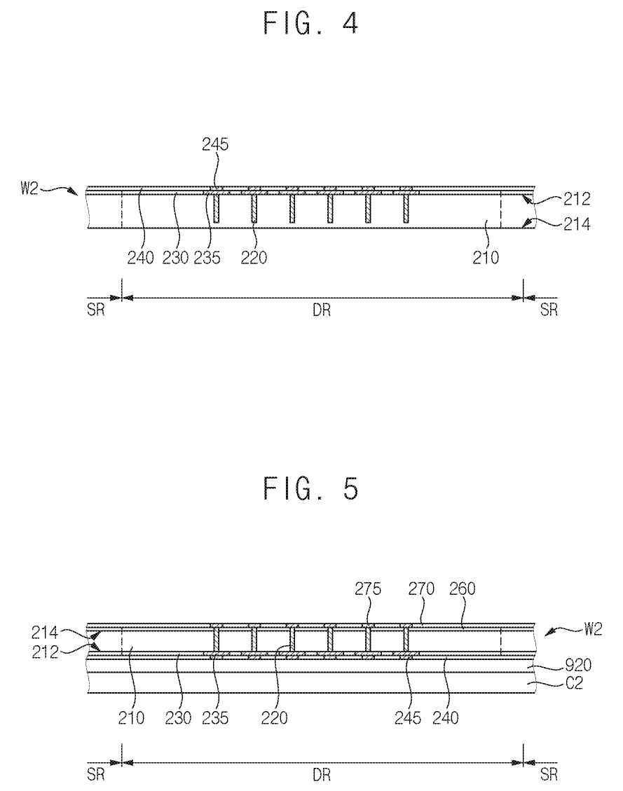

Referring to FIG. 4, a second wafer W2 may be provided.

In some implementations, the second wafer W2 may include a second substrate 210 having first and second surfaces 212 and 214 opposite to each other in the vertical direction. Additionally, the second wafer W2 may include a plurality of die regions DR and a scribe lane region SR surrounding each of the die regions DR. The second wafer W2 may be cut along the scribe lane region SR by a sawing process to be singulated into a plurality of second semiconductor chips.

In the die region DR, a circuit device may be formed on the first surface 212 of the second substrate 210. The circuit device may include a memory device. The circuit device may include circuit patterns, and a third insulating interlayer may be formed on the first surface 212 of the second substrate 210 to cover the circuit patterns.

A fourth insulating interlayer 230 may be formed on the third insulating interlayer, and may include a second wiring structure 235 therein.

In some implementations, a second through electrode structure 220 extending in the vertical direction through an upper portion of the second substrate 210, that is, a portion of the

second substrate 210 adjacent to the first surface 212 thereof may be formed. In some implementations, a plurality of second through electrode structures 220 may be spaced apart from each other in the horizontal direction in each of the die regions DR of the second wafer W2.

In some implementations, the second through electrode structure 220 may include a second through electrode extending in the vertical direction, a second barrier pattern covering a sidewall and a lower surface of the second through electrode, and a second insulation pattern covering a sidewall and a lower surface of the second barrier pattern.

A second bonding layer 240 including a second bonding pad 245 therein may be formed on the fourth insulating interlayer 230 including the second wiring structure 235.

In some implementations, a plurality of second bonding pads 245 may be spaced apart from each other in the horizontal direction, and some of the second bonding pads 245 may contact upper surfaces of the second wiring structures 235, respectively.

In some implementations, the second bonding layer 240 may include an insulating material, e.g., silicon carbonitride, silicon nitride, silicon oxide, etc., and the second bonding pad 245 may include a metal, e.g., copper.

Referring to FIG. 5, a second temporary bonding layer 920 may be attached to a second carrier substrate C2, and the second temporary bonding layer 920 may be bonded to an upper surface of the second bonding layer 240 including the second bonding pad 245 on the second wafer W2 so that the second carrier substrate C2 may be bonded to the second wafer W2.

The second temporary bonding layer 920 may include a material that may lose adhesion by irradiation of light, e.g., UV light or heat. In some implementations, the second temporary bonding layer 920 may include glue.

After flipping the second wafer W2, a portion of the second substrate 210 adjacent to the second surface 214 of the second substrate 210 may be removed by, e.g., a grinding process to expose an upper portion of the second through electrode structure 220.

In some implementations, during the grinding process, an upper portion of the second insulation pattern included in the second through electrode structure 220 may also be removed, so that an upper surface and an upper outer sidewall of the second barrier pattern may be exposed.

A second protective layer structure may be formed on the second surface 214 of the second substrate 210 to cover the second through electrode structure 220, and a planarization process may be performed on the second protective layer structure until an upper surface of the second through electrode of the second through electrode structure 220 is exposed to form a second protective pattern structure 260.

In some implementations, the first protective layer structure may include fourth to sixth protective layers sequentially stacked in the vertical direction, and during the planarization process, the sixth protective layer may be removed and the fifth protective layer may partially remain. Thus, the second protective pattern structure 260 may include fourth and fifth protective patterns sequentially stacked in the vertical direction. An upper outer sidewall of a portion of the fourth protective pattern adjacent to the second through electrode structure 220 may be covered by the fifth protective pattern.

A third bonding layer 270 including a third bonding pad 275 therein may be formed on the second protective pattern structure 260 and the second through electrode structure 220.

In some implementations, a plurality of third bonding pads 275 may be spaced apart from each other in the horizontal direction, and may contact upper surfaces of the second through electrode structures 220, respectively.

In some implementations, the third bonding layer 270 may include an insulating material, e.g., silicon carbonitride, silicon nitride, silicon oxide, etc., and the third bonding pad 275 may include a metal, e.g., copper.

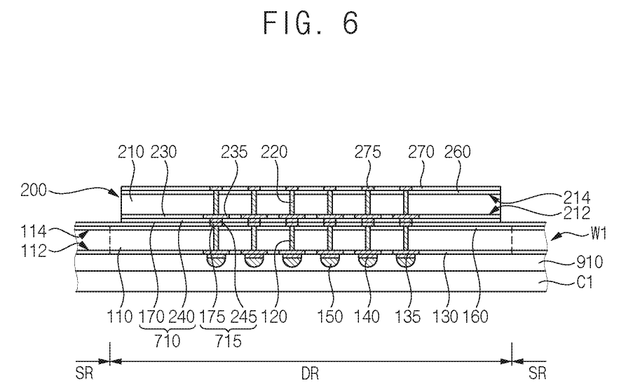

Referring to FIG. 6, after flipping the second wafer W2, the second wafer W2 may be attached to an upper surface of a release tape on a frame having a shape of, e.g., a ring.

The release tape may contact an upper surface of the third bonding layer 270 on the second surface 214 of the second wafer W2.

The second temporary bonding layer 920 attached to the second carrier substrate C2 may be separated from the second bonding layer 240, so that the second carrier substrate C2 may be separated from the second wafer W2.

The wafer W2 may be cut along the scribe lane region SR by a sawing process to form second semiconductor chips 200.

A thickness in the vertical direction of each of the second semiconductor chips 200 including the second substrate 210, the third insulating interlayer, the fourth insulating interlayer 230, the second through electrode structure 220 and the second protective pattern structure 260 may be in a range of about 30um to about 100um, and a thickness in the vertical direction of each of the second and third bonding layers 240 and 270 may be equal to or less than about 1um.

Each of the second semiconductor chips 200 may be separated from the release tape, and may be mounted on the first wafer W1 such that the second bonding layer 240 on the second semiconductor chip 200 may contact an upper surface of the first bonding layer 170 on the first wafer W1.

Each of the second semiconductor chips 200 may be mounted on a corresponding one of the die regions DR of the first wafer W1, and the second bonding pad 245 of the second semiconductor chip 200 may contact an upper surface of the bonding pad 175 of the first semiconductor chip. The first and second bonding layers 170 and 240 may be bonded with each other to form a first bonding layer structure 710, and the first and second bonding pads 175 and 245 may be bonded with each other to form a first bonding pad structure 715. For example, each of the second semiconductor chips 200 may be bonded to the first wafer W1 by a hybrid copper bonding (HCB) process.

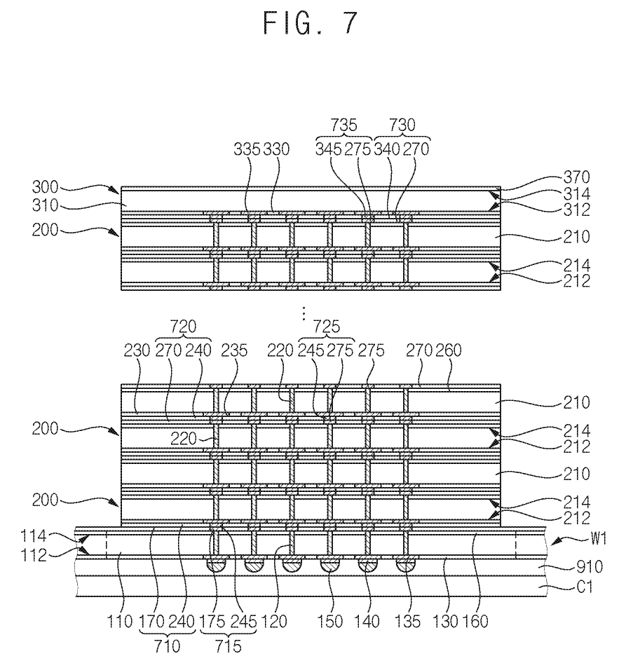

Referring to FIG. 7, processes substantially the same as or similar to those illustrated with respect to FIGS. 4 to 6 may be performed so that a plurality of second semiconductor chips 200 may be further bonded to each of the second semiconductor chips 200 on the first wafer W1.

The second bonding layer 240 on an upper one of the second semiconductor chips 200 may contact the third bonding layer 270 on a lower one of the second semiconductor chips 200, and the second and third bonding pads 245 and 275 may contact each other. Thus, the second and third bonding layers 240 and 270 may be bonded to each other to form a second bonding layer structure 720, and the second and third bonding pads 245 and 275 may be bonded to each other to form a second bonding pad structure 725.

As illustrated above, each of the second semiconductor chips 200 may have a thin thickness of about 30um to about 100um, and thus, when the second semiconductor chips 200 are bonded to each other through the second bonding layer structure 720, even if voids are generated between the second and third bonding layers 240 and 270, pressure may be applied to an uppermost one of the second semiconductor chips 200 so that the voids may be expelled outwardly. Accordingly, the voids may not remain in the second bonding layer structure 720 and the second semiconductor chips 200 may be well bonded to each other.

Processes substantially the same as or similar to those illustrated with respect to FIGS. 4 to 6 may be performed so that a third semiconductor chip 300 may be bonded to the uppermost one of the second semiconductor chips 200.

The third semiconductor chip 300 may include a third substrate 310 having first and second surfaces 312 and 314 opposite to each other in the vertical direction, and a fifth insulating interlayer and a sixth insulating interlayer including a third wiring structure 335 may be sequentially stacked on the first surface 312 of the third substrate 310.

A fourth bonding layer 340 including a fourth bonding pad 345 may be formed on a lower surface of the sixth insulating interlayer 330, and a fifth bonding layer 370 may be formed on the second surface 314 of the third substrate 310.

The fourth bonding layer 340 on the third semiconductor chip 300 may contact the third bonding layer 270 on the uppermost one of the second semiconductor chips 200, and the fourth and third bonding pads 345 and 275 may contact each other. Thus, the third and fourth bonding layers 270 and 340 may be bonded to each other to form a third bonding layer structure 730, and the third and fourth bonding pads 275 and 345 may be bonded to each other to form a third bonding pad structure 735.

In some implementations, each of the fourth and fifth bonding layers 340 and 370 may include an insulating material, e.g., silicon carbonitride, silicon nitride, silicon oxide, etc., and the fourth bonding pad 345 may include a metal, e.g., copper.

In some implementations, a thickness in the vertical direction of the third semiconductor chip 300 including the third substrate 310, the fifth insulating interlayer and the sixth insulating interlayer 330 may be in a range of about 30um to about 100um, and a thickness in the vertical direction of each of the fourth and fifth bonding layers 340 and 370 may be equal to or less than about 1um.

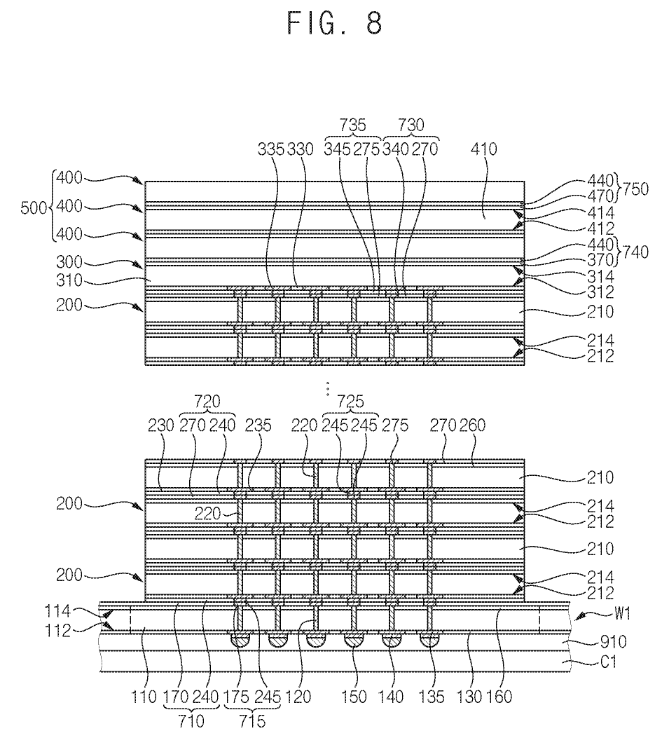

Referring to FIG. 8, processes substantially the same as or similar to those illustrated with respect to FIGS. 4 to 6 may be performed so that a plurality of dummy chips 400 may be bonded to the third semiconductor chip 300.

Each of the dummy chips 400 may include a fourth substrate 410 having first and second surfaces 412 and 414 opposite to each other in the vertical direction, a sixth bonding layer 440 may be formed on the second surface 412 of the fourth substrate 410, and a seventh bonding layer 470 may be formed on the second surface 414 of the fourth substrate 410.

However, in some in some implementations, the seventh bonding layer 470 may not be formed on the second surface 414 of the fourth substrate 410 included in an uppermost one of the dummy chips 400, which is shown in FIG. 8.

The sixth bonding layer 440 on a lowermost one of the dummy chips 400 may contact the fifth bonding layer 370 on an upper surface of the third semiconductor chip 300, and the fifth and sixth bonding layers 370 and 440 may be bonded to each other to form a fourth bonding layer structure 740. The sixth bonding layer 440 on a lower surface of an upper one of the dummy chips 400 may contact the seventh bonding layer 470 on an upper surface of a lower one of the dummy chips 400, and the sixth and seventh bonding layers 440 and 470 may be bonded to each other to form a fifth bonding layer structure 750.

In some implementations, each of the sixth and seventh bonding layers 440 and 470 may include an insulating material, e.g., silicon carbonitride, silicon nitride, silicon oxide, etc.

In some implementations, a thickness in the vertical direction of the dummy chip 400 may be in a range of about 30um to about 60um, and a thickness in the vertical direction of each of the sixth and seventh bonding layers 440 and 470 may be equal to or less than about 1um.

As each of the dummy chips 400 has the thin thickness of about 30um to about 60um, when the lowermost one of the dummy chips 400 and the third semiconductor chip 300 are bonded to each other through the fourth bonding layer structure 740 or the dummy chips 400 are bonded to each other through the fifth bonding layer structure 750, even if voids are generated between the fifth and sixth bonding layers 370 and 440 or between the sixth and seventh bonding layers 440 and 470, pressure may be applied to the uppermost one of the dummy chips 400 so as to expel the voids outwardly. Thus, the voids may not remain in the fourth and fifth bonding layer structures 740 and 750, and the lowermost one of the dummy chip 400 and the third semiconductor chip 300 or the dummy chips 400 may be well bonded to each other.

The dummy chips 400 stacked in the vertical direction and the fifth bonding layer structure 750 between the dummy chips 400 may collectively form a dummy chip stack structure 500.

Referring to FIG. 1 again, a molding member 600 may be formed on the first wafer W1 to cover the second and third semiconductor chips 200 and 300, the first to fourth bonding layer structures 710, 720, 730 and 740 and the dummy chip stack structure 500, and the first wafer W1 may be cut along the scribe lane region SR by, e.g., a sawing process so as to be singulated into a plurality of first semiconductor chips 100.

During the sawing process, the molding member 600 may also be cut to cover sidewalls of the second and third semiconductor chips 200 and 300, the first to fourth bonding layer structures 710, 720, 730 and 740 and the dummy chip stack structure 500.

For example, a grinding process may be performed on the molding member 600 until the upper surface of the uppermost one of the dummy chips 400 is exposed, and the first temporary bonding layer 910 and the first carrier substrate C1 may be separated from each of the first semiconductor chips 100 to complete the manufacturing of the semiconductor package.

As illustrated above, each of the second semiconductor chips 200 that may be stacked on the first wafer W1 and bonded to each other by an HCB process may have the thin thickness, and thus, even if the voids are generated in the second bonding layer structure 720 between the second semiconductor chips 200, pressure may be applied to the upper surface of the uppermost one of the second semiconductor chips 200 to expel the voids outwardly, so that the second semiconductor chips 200 may be well bonded to each other.

Likewise, each of the dummy chips 400 that may be stacked on the third semiconductor chip 300 and bonded to each other by an HCB process may have the thin thickness, and thus, even if the voids are generated in the fourth bonding layer structure 740 interposed between the third semiconductor chip 300 and the lowermost one of the dummy chips 400 or in the fifth bonding layer structure 750 interposed between the dummy chips 400, pressure may be applied to the upper surface of the uppermost one of the dummy chips 400 to expel the voids outwardly, so that the third semiconductor chip 300 and the dummy chip 400 or the dummy chips 400 may be well bonded to each other.

If a single dummy chip having a thickness in the vertical direction similar to the sum of the thicknesses in the vertical direction of the thin dummy chips 400 is stacked, when pressure is applied to the single dummy chip, the single dummy chip may have a high stiffness so that the voids may not be expelled outwardly, so that the fifth and sixth bonding layers 370 and 440 of the fourth bonding layer structure 740 may not be well bonded to each other.

However, in some implementations as described herein, instead of the single dummy chip having the thick thickness, a plurality of dummy chips 400 having the thin thicknesses may be stacked on the third semiconductor chip 300, so that the voids in the fourth bonding layer structure 740 between the lowermost one of the dummy chips 400 and the third semiconductor chip 300 and the voids in the fifth bonding layer structure 750 between the dummy chips 400 stacked in the vertical direction may be easily expelled.

For example, if pressure is applied to the upper surface of each of the dummy chips 400 using a bonding tool having a convex lower surface, each of the dummy chips 400 has the thin thickness so as to have a low stiffness and be easily deformed. Thus, the voids in the fourth bonding layer structure 740 between the lowermost one of the dummy chips 400 and the third semiconductor chip 300 and the voids in the fifth bonding layer structure 750 between the dummy chips 400 stacked in the vertical direction may be easily expelled by the bonding tool.

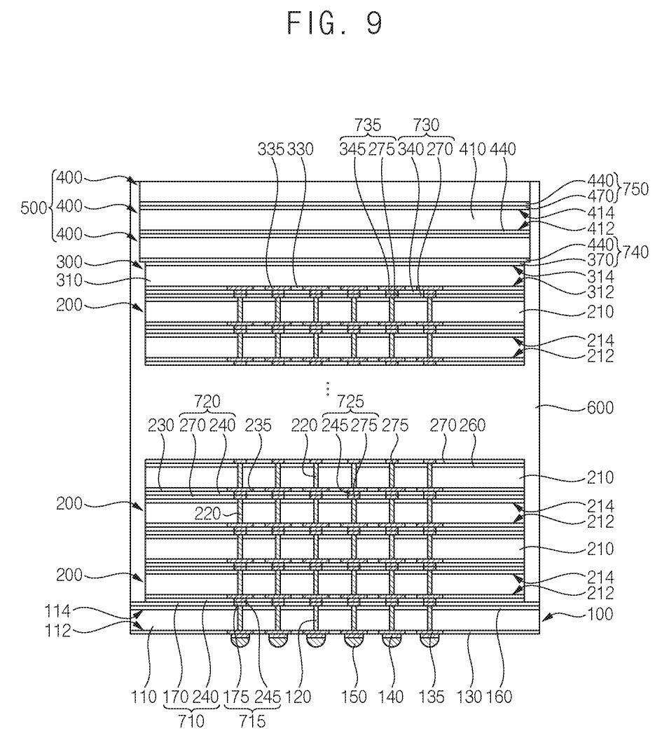

FIGS. 9 to 11 are cross-sectional views illustrating examples of semiconductor packages. These semiconductor packages may be substantially the same as or similar to that of FIG. 1 (e.g., except for the dummy chip stack structure as described), and thus repeated explanations are omitted herein.

Referring to FIG. 9, a planar area of the dummy chip stack structure 500 may be greater than a planar area of each of the second and third semiconductor chips 200 and 300.

In some implementations, in a plan view, each of the second and third semiconductor chips 200 and 300 may be arranged in a region in which the dummy chip stack structure 500 is disposed, and thus a width in the horizontal direction of the dummy chip stack structure 500 may be greater than a width in the horizontal direction of each of the second and third semiconductor chips 200 and 300. For example, the second and third semiconductor chips 200 and 300 may be completely overlapped by the dummy chip stack structure 500 (e.g., by the dummy chips 400).

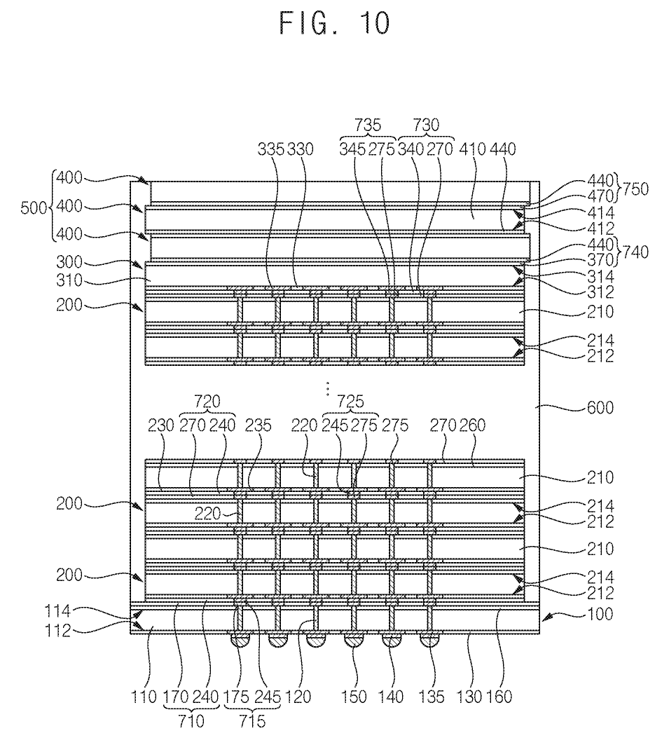

Referring to FIG. 10, sidewalls of the dummy chips 400 included in the dummy chip stack structure 500 may not be aligned with each other in the vertical direction (e.g., may be offset in a horizontal direction). For example, this arrangement may occur due to misalignment of the dummy chips 400 when the dummy chips 400 are stacked in the vertical direction.

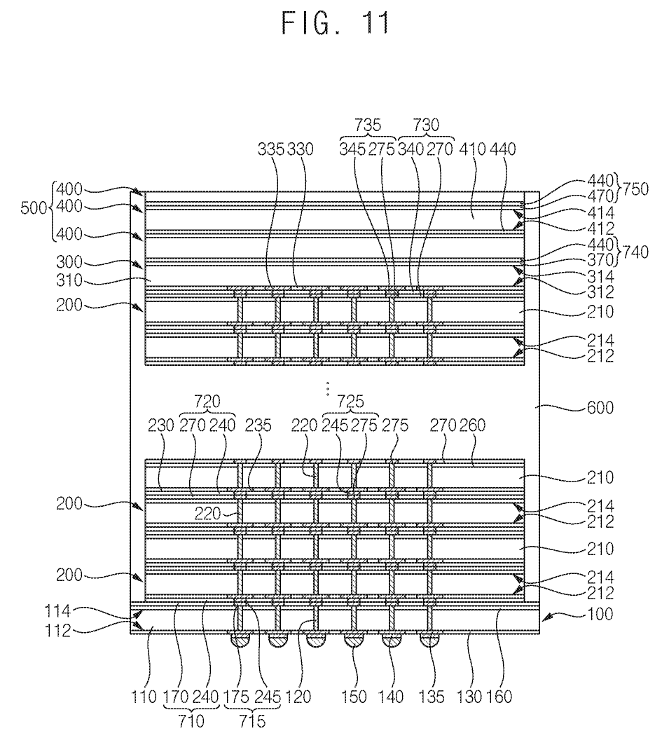

Referring to FIG. 11, a thickness in the vertical direction of the uppermost one of the dummy chips 400 included in the dummy chip stack structure 500 may be less than a thickness in the vertical direction of each other one of the dummy chips 400 included in the dummy chip stack structure 500. For example, during the grinding process on the molding member 600, an upper portion of the uppermost one of the dummy chips 400 may be partially removed so that the thickness in the vertical direction of the uppermost one of the dummy chips 400 may be reduced.

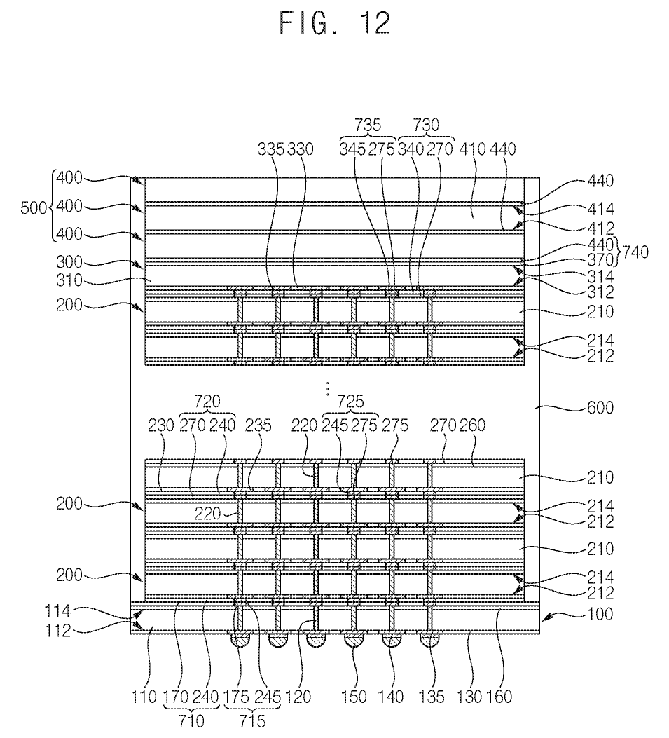

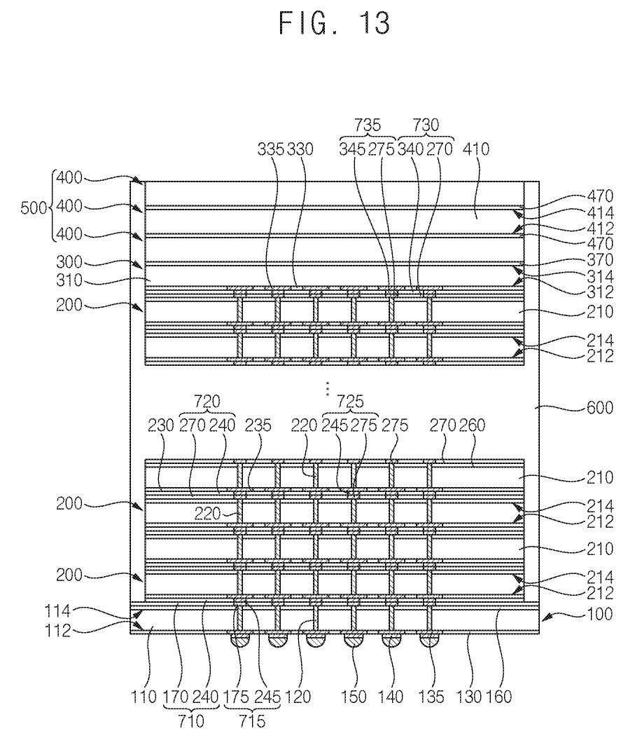

FIGS. 12 and 13 are cross-sectional views illustrating examples of semiconductor packages. These semiconductor packages may be substantially the same as or similar to that of FIG. 1 (e.g., except for the dummy chip stack structure as described), and thus repeated explanations are omitted herein.

Referring to FIG. 12, the dummy chip stack structure 500 may include the dummy chips 400 stacked in the vertical direction and the sixth bonding layer 440 on the first surface 412 of each of the dummy chips 400, and the seventh bonding layer 470 may not be disposed on the second surface 414 of each of the dummy chips 400.

Referring to FIG. 13, the dummy chip stack structure 500 may include the dummy chips 400 stacked in the vertical direction and the seventh bonding layer 470 on the second surface 414 of each of the dummy chips 400, and the sixth bonding layer 440 may not be disposed on the first surface 412 of each of the dummy chips 400.

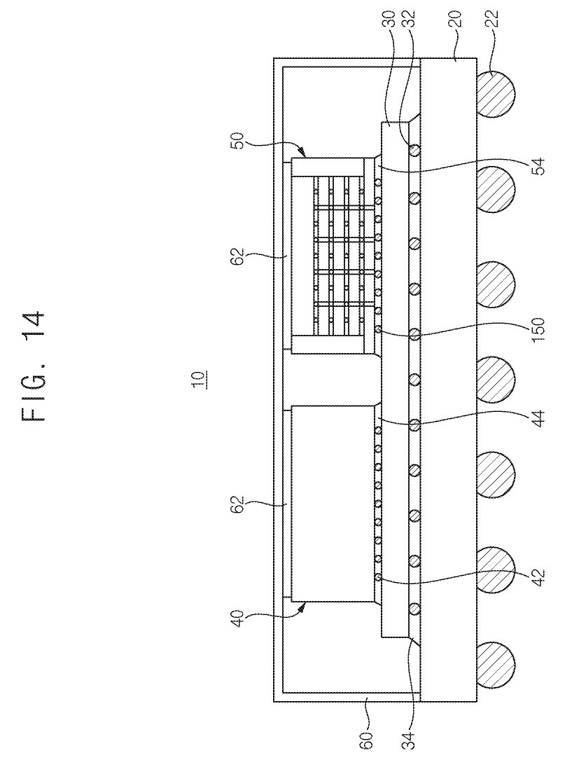

FIG. 14 is a cross-sectional view illustrating an example of an electronic device. This electronic device may include a semiconductor package as described herein as a second semiconductor device 50. For example, any of the semiconductor packages shown in FIGS. 1 and 9 to 13 may be included as the second semiconductor device 50. It will be understood that the semiconductor packages described herein can be used in contexts besides that of the electronic device of FIG. 14.

Referring to FIG. 14, an electronic device 10 may include a package substrate 20, an interposer 30, a first semiconductor device 40 and the second semiconductor device 50. The electronic device 10 may further include first, second and third underfill members 34, 44 and 54, a heat slug 60 and a heat dissipation member 62.

In some implementations, the electronic device 10 may be a memory module having a 2.5D package structure, and thus may include the interposer 30 for electrically connecting the first and second semiconductor devices 40 and 50 to each other.

In some implementations, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may be a semiconductor package such as an HBM package.

In some implementations, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a third conductive connection member 32. In some implementations, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the third conductive connection member 32. The third conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a flip chip bonding process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a fourth conductive connection member 42. For example, the fourth conductive connection member 42 may include, e.g., a micro-bump.

As another example, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by, e.g., a flip chip bonding process. In this case, conductive pads of the second semiconductor device 50 may be electrically connected to conductive pads of the interposer 30 by the first conductive connection member 150.

Although a single first semiconductor device 40 and a single second semiconductor device 50 are illustrated as disposed on the interposer 30, the number(s) thereof are not limited thereto, and a plurality of first semiconductor devices 40 and/or a plurality of second conductive devices 50 may be disposed on the interposer 30.

In some implementations, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44 and 54 may include an adhesive containing an epoxy material.

The semiconductor device 50 may include a buffer die and a plurality of memory dies sequentially stacked on the buffer die. The buffer die and the memory dies may be electrically connected to each other by through electrodes, e.g., TSVs, and the through electrodes may be electrically connected to each other by conductive connection members. Data signals and control signals may be transferred to the buffer die and the memory dies by the through electrodes.

In some implementations, the heat slug 60 may be formed on the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be disposed at a lower portion of the package substrate 20, and a second conductive connection member 22 may be disposed beneath the conductive pad. In some implementations, a plurality of second conductive connection members 22 may be spaced apart from each other in the horizontal direction. The second conductive connection member 22 may be, e.g., a solder ball. The electronic device 10 may be mounted on a module board via the second conductive connection members 22 to form a memory module.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination. For example, features shown in the semiconductor packages of any of FIGS. 1 and 9 to 13 may be included in the semiconductor package of any other of FIGS. 1 and 9 to 13.

The foregoing is illustrative of various examples. Although these examples have been described, those skilled in the art will readily appreciate that many modifications are possible without materially departing from the scope of the present disclosure.

What is claimed is:

1. A semiconductor package comprising:
a buffer die;
a plurality of middle core dies stacked in a vertical direction on the buffer die;
a top core die on an uppermost one of the plurality of middle core dies;
a plurality of dummy dies stacked in the vertical direction on the top core die;
a first bonding layer structure between adjacent ones of the plurality of middle core dies, wherein the first bonding layer structure includes a first bonding pad structure;
a second bonding layer structure between the top core and a lowermost one of the plurality of dummy dies; and
a third bonding layer structure between adjacent ones of the plurality of dummy dies.

2. The semiconductor package of claim 1, wherein the third bonding layer structure includes first and second bonding layers stacked in the vertical direction.

3. The semiconductor package of claim 2, wherein each of the first and second bonding layers includes silicon carbonitride, silicon nitride, or silicon oxide.

4. The semiconductor package of claim 2, wherein a thickness in the vertical direction of each of the first and second bonding layers is equal to or less than 1 um.

5. The semiconductor package of claim 1, wherein a thickness in the vertical direction of the third bonding layer structure is equal to or less than 1 um.

6. The semiconductor package of claim 1, wherein a thickness in the vertical direction of each of the plurality of dummy dies is equal to or less than a thickness in the vertical direction of each of the plurality of middle core dies.

7. The semiconductor package of claim 6, wherein the thickness in the vertical direction of each of the plurality of dummy dies is in a range from 30 um to 60 um, and the thickness in the vertical direction of each of the plurality of middle core dies is in a range from 30 um to 100 um.

8. The semiconductor package of claim 1, wherein each of the plurality of middle core dies includes:
a first substrate;
a first insulating interlayer on a lower surface of the first substrate, wherein the first insulating interlayer includes a first wiring structure;
a through electrode extending in the first substrate in the vertical direction; and
a protective pattern structure on the first substrate and surrounding an upper portion of the through electrode,
wherein the through electrode contacts the first bonding layer structure.

9. The semiconductor package of claim 8, wherein the top core die includes:
a second substrate; and
a second insulating interlayer on a lower surface of the second substrate, wherein the second insulating interlayer includes a second wiring structure,
wherein the semiconductor package further includes a fourth bonding layer structure between the uppermost one of the plurality of middle core dies and the top core die, and
wherein the fourth bonding layer structure includes a second bonding pad structure contacting the through electrode of the uppermost one of the plurality of middle core dies.

10. The semiconductor package of claim 9, wherein each of the first and second bonding pad structures includes copper.

11. The semiconductor package of claim 1, wherein a sum of thicknesses in the vertical direction of the plurality of dummy dies is greater than a thickness in the vertical direction of each of the plurality of middle core dies, and a thickness in the vertical direction of the top core die.

12. The semiconductor package of claim 1, wherein a planar area of each of the plurality of dummy dies is greater than a planar area of each of the plurality of middle core dies, and a planar area of the top core die.

13. The semiconductor package of claim 1, wherein the plurality of middle core dies are bonded to one another by copper-copper bonds.

14. A semiconductor package comprising:
a first semiconductor chip;
a plurality of second semiconductor chips stacked in a vertical direction on the first semiconductor chip, each of the plurality of second semiconductor chips including:
a substrate; and
a through electrode extending in the substrate in the vertical direction;
a third semiconductor chip on an uppermost one of the plurality of second semiconductor chips;
a plurality of dummy chips stacked in the vertical direction on the third semiconductor chip;
a first bonding layer structure between adjacent ones of the plurality of second semiconductor chips, wherein the first bonding layer structure includes a first bonding pad structure configured to be electrically connected to the through electrode of at least one of the plurality of second semiconductor chips;
a second bonding layer structure between the uppermost one of the plurality of second semiconductor chips and the third semiconductor chip, wherein the second bonding layer structure includes a second bonding pad structure configured to be electrically connected to the through electrode of the uppermost one of the plurality of second semiconductor chips;
a third bonding layer structure between the third semiconductor chip and a lowermost one of the plurality of dummy chips; and
a fourth bonding layer structure between adjacent ones of the plurality of dummy chips.

15. The semiconductor package of claim 14, wherein the fourth bonding layer structure includes first and second bonding layers stacked in the vertical direction, and
wherein each of the first and second bonding layers includes silicon carbonitride, silicon nitride, or silicon oxide.

16. A semiconductor package comprising:
a first semiconductor chip including:
a first substrate, and
a first through electrode extending in the first substrate in a vertical direction;
a first bonding layer structure on the first semiconductor chip, wherein the first bonding layer structure includes a first bonding pad structure configured to be electrically connected to the first through electrode;
a plurality of second semiconductor chips stacked in the vertical direction on the first bonding layer, wherein each of the plurality of second semiconductor chips includes:
a second substrate, and
a second through electrode extending in the second substrate in the vertical direction;
a second bonding layer structure between adjacent ones of the plurality of second semiconductor chips, wherein the second bonding layer structure includes a second bonding pad structure configured to be electrically connected to the second through electrode of at least one of the plurality of second semiconductor chips;
a third bonding layer structure on an uppermost one of the plurality of second semiconductor chips, wherein the third bonding layer structure includes a third bonding pad structure configured to be electrically connected to the second through electrode of the uppermost one of the plurality of second semiconductor chips;
a third semiconductor chip on the third bonding layer structure;
a fourth bonding layer structure on the third semiconductor chip;
a plurality of dummy chips stacked in the vertical direction on the fourth bonding layer structure;
a fifth bonding layer structure between adjacent ones of the plurality of dummy chips; and
a molding member on the first semiconductor chip, wherein the molding member covers sidewalls of the first semiconductor chip, the plurality of second semiconductor chips, the third semiconductor chip, the plurality of dummy chips, and the first to fifth bonding layer structures.

17. The semiconductor package of claim 16, wherein the fifth bonding layer structure includes first and second bonding layers stacked in the vertical direction.

18. The semiconductor package of claim 17, wherein each of the first and second bonding layers includes silicon carbonitride, silicon nitride, or silicon oxide.

19. The semiconductor package of claim 16, wherein a thickness in the vertical direction of each of the plurality of dummy chips is equal to or less than a thickness in the vertical direction of each of the plurality of second semiconductor chips and a thickness in the vertical direction of the third semiconductor chip.

20. The semiconductor package of claim 16, wherein the first semiconductor chip includes a logic device, and each of the plurality of second semiconductor chips and the third semiconductor chip includes a memory device.
